(19) United States
(12) Patent Application Publication
(10) Pub. No.: US 2026/0215218 A1
(43) Pub. Date: Jul. 23, 2026

(54) APPARATUS AND METHOD FOR PROCESSING WAFER

(71) Applicants: TSMC CHINA COMPANY LIMITED, Shanghai (CN); TAIWAN SEMICONDUCTOR MANUFACTURING COMPANY, LTD., Hsinchu (TW)

(72) Inventors: Ronghua ZHANG, Shanghai City (CN); Honghua ZHU, Shanghai City (CN); Lan HUANG, Shanghai City (CN); Longlong MA, Shanghai City (CN); Xu JI, Shanghai City (CN); Yi LUO, Shanghai City (CN); Lisheng HANG, Shanghai City (CN)

(73) Assignees: TSMC CHINA COMPANY LIMITED, Shanghai (CN); TAIWAN SEMICONDUCTOR MANUFACTURING COMPANY, LTD., Hsinchu (TW)

(21) Appl. No.: 19/051,660

(22) Filed: Feb. 12, 2025

(30) Foreign Application Priority Data
Jan. 17, 2025 (CN) 202510082360.9

(51) Int. Cl. H01L 21/68; H01L 21/67; H01L 21/687

(52) U.S. Cl. CPC H10P 72/53; H10P 72/0608; H10P 72/7602

(57) ABSTRACT

A method includes vertically moving a shelf in a chamber; using a distance sensor, measuring a vertical position of the shelf; determining whether a vertical position of a target stage of the shelf is within an acceptable range; and in response to the vertical position of the target stage is within an acceptable range, moving a wafer onto or away from the target stage.

### PRIORITY CLAIM AND CROSS-REFERENCE

The present application claims priority to China Application Serial Number 202510082360.9, filed Jan. 17, 2025, which is herein incorporated by reference in its entirety.

### BACKGROUND

During the manufacture of a semiconductor device, the device is usually processed on many workstations or processing machines. The transportation or handling of semi-finished devices or work-in-process (WIP) components is an important aspect of the entire manufacturing process. Due to the fragile nature of chips, the handling of work-in-process components (such as semiconductor wafers) is particularly important in the manufacture of integrated circuit (IC) chips. In addition, when manufacturing integrated circuit products, multiple manufacturing steps (that is, as many as hundreds) are usually required to complete the manufacturing process. Semiconductor wafers or integrated circuit wafers must be stored or transported between various processing stations to perform various manufacturing processes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a diagrammatic top view of a semiconductor fabrication apparatus according to some embodiments of the present disclosure.

FIG. 1B is a schematic diagram of an auxiliary chamber of the semiconductor fabrication apparatus of FIG. 1A.

FIG. 1C is a schematic diagram of the auxiliary chamber of FIG. 1B with a distance sensor according to some embodiments of the present disclosure.

FIG. 2 is a schematic diagram of a distance sensor of FIG. 1C.

FIG. 3A is a flow chart of a method for processing a wafer according to some embodiments of the present disclosure.

FIG. 3B shows pulses versus time for processing a wafer according to some embodiments of the present disclosure.

FIGS. 4A-4D illustrate an example of moving the wafer onto a target stage in accordance with some embodiments of the present disclosure.

FIGS. 5A-5D illustrate an example of moving the wafer away from a target stage in accordance with some embodiments of the present disclosure.

FIG. 6 is a perspective view of a distance sensor held by a fixing element according to some embodiments of the present disclosure.

FIG. 7A is a schematic diagram of a fixing element of FIG. 6.

FIG. 7B is a cross-sectional view of a fixing element of FIG. 6.

FIG. 8A is a schematic diagram of a semiconductor fabrication apparatus according to some embodiments of the present disclosure.

FIG. 8B is a cross-sectional view of an auxiliary chamber of the semiconductor fabrication apparatus of FIG. 8A according to some embodiments of the present disclosure.

FIG. 8C is a schematic diagram illustrating a first exemplary configuration of various configurations of FIG. 8B.

FIGS. 8D and 8E are schematic diagrams illustrating a second exemplary configuration of various configurations of FIG. 8B.

FIG. 9A is a perspective view of a distance sensor held by a fixing element according to some embodiments of the present disclosure.

FIG. 9B is a schematic diagram of a fixing element of FIG. 9A.

FIG. 9C is a cross-sectional view of a fixing element of FIG. 9A.

FIG. 10 is a schematic diagram of a load lock chamber of the semiconductor fabrication apparatus of FIG. 8A.

FIG. 11A is a flow chart of a method for processing a wafer according to some embodiments of the present disclosure.

FIG. 11B shows pulses versus time for processing a wafer according to some embodiments of the present disclosure.

FIG. 12A is a schematic diagram of a process chamber of a semiconductor fabrication apparatus according to some embodiments of the present disclosure.

FIGS. 12B and 12C are schematic diagram of a motor and a distance sensor of a process chamber of the semiconductor fabrication apparatus of FIG. 12A.

FIG. 13A is a flow chart of a method for processing a wafer according to some embodiments of the present disclosure.

FIG. 13B shows pulses versus time for processing a wafer according to some embodiments of the present disclosure.

FIG. 14 is a block diagram of a semiconductor fabrication apparatus according to some embodiments of the present disclosure.

FIG. 15 is a detection result of the distance sensors according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,” or “substantially” can be inferred if not expressly stated.

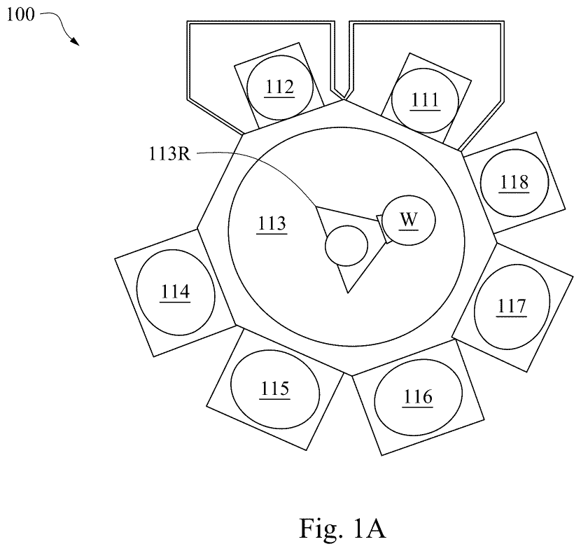

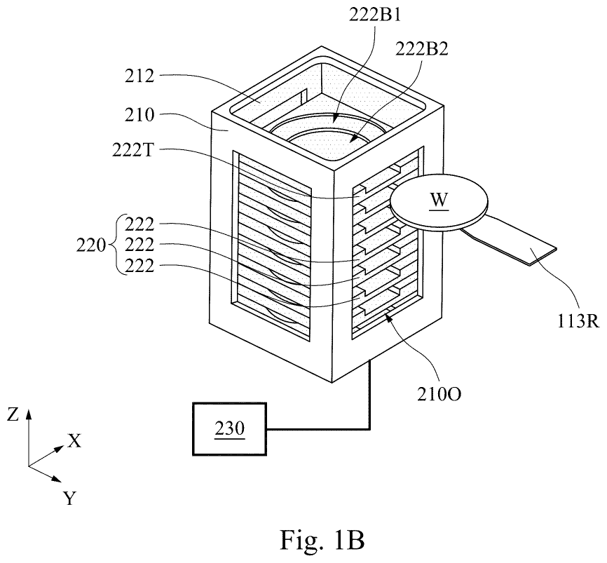

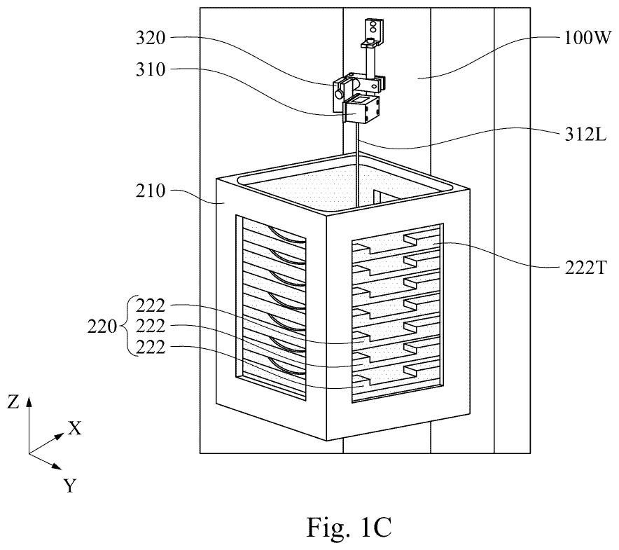

FIG. 1A is a diagrammatic top view of a semiconductor fabrication apparatus 100. In the illustrated embodiments, the semiconductor fabrication apparatus 100 includes a cluster tool, including load lock chambers 111, 112, a wafer handling chamber 113, and plural chambers 114-118. In some embodiments, the chambers 114-117 are processing chambers, and the chamber 118 is an auxiliary chamber. The cluster tool may also include other chambers, such as wait chambers between the wafer handling chamber 113 and the load lock chambers 111, 112 in some other embodiments. The load lock chambers 111 and 112 may be configured for transferring wafers W into and out of the cluster tool, respectively. In various embodiments, the cluster tool (including the wafer handling chamber 113 and the chambers 114-118) is under vacuum, and the load lock chambers 111 and 112 may “pump down” the wafers introduced into the cluster tool (e.g., by way of the vacuum system). In some embodiments, the load lock chambers 111 and 112 may be adapted to receive and release a single wafer or a plurality of wafers (e.g., loaded into a cassette). By way of example, the load lock chambers 111 and 112 may be separated from the wafer handling chamber 113 by way of a gate valve, allowing the wafer handling chamber 113 to remain under vacuum when one or both of the load lock chambers 111 and 112 are vented.

The wafer handling chamber 113 may also be referred to as a buffer chamber. In various embodiments, the wafer handling chamber 113 is equipped with a transfer arm 113R (e.g., robotic transfer arm) operable to transfer the wafer W. The transfer arm 113R may have a blade for holding a wafer W. The transfer arm 113R may automatically move smoothly along any of a horizontal and/or vertical axis, so as to transfer wafers/substrates W between the load lock chambers 111 and 112 and any of the chambers 114-118.

The processing chambers 114-117 may be configured to perform a number of substrate processing operations, such as atomic layer deposition (ALD), chemical vapor deposition (CVD), physical vapor deposition (PVD), etching, film coating, pre-treatment/pre-soak, de-gassing, as well as annealing, and/or other suitable processing or operations in front-end-of-line (FEOL) or back-end-of-line (BEOL) process. For example, one or more of the processing chambers 114-117 may be configured to deposit various dielectric layers and metal layers (e.g., TiN layer, AlCu layer, or the like), coat an anti-reflection layer, thermally pre-treat the wafers W, and/or other suitable processing or operations. In various embodiments, the cluster tool may have more or less processing chambers, for example, for a desired process to be performed by the cluster tool.

The auxiliary chamber 118 may temporally keep the wafers W before, during, or after the processes of the processing chambers 114-117. In some embodiments, the auxiliary chamber 118 may be equipped with a cooling system for cooling down the wafers W, and the auxiliary chamber 118 may be referred to as a cool-down chamber.

In the semiconductor fabrication process conducted by the semiconductor fabrication apparatus 100, a wafer W may be transferred from one of the load lock chambers 111 and 112 to the processing chamber 114 (e.g., via the wafer handling chamber 113) for being subjected to a first process. In some embodiments, the cluster tool may further include an orientor chamber, and the wafer W moved from said one of the load lock chambers 111 and 112 may be oriented in the orientor chamber (not shown) first, prior to entering the processing chamber 114. In some embodiments, the wafer W may be transferred from the processing chamber 114 to the processing chamber 115 (e.g., via the wafer handling chamber 113) for being subjected to a second process, the wafer W may then be transferred from the processing chamber 115 to the processing chamber 116 (e.g., via the wafer handling chamber 113) for being subjected to a third process, and/or the wafer W may then be transferred from the processing chamber 116 to the processing chamber 117 (e.g., via the wafer handling chamber 113) for being subjected to a fourth process. In some embodiments, after the first, second, third and/or fourth processes, the wafer W may then be transferred from the processing chamber 114, 115, 116, or 117 to the auxiliary chamber 118 (e.g., via the wafer handling chamber 113) for being cooled down. The wafer W that is processed through the first, second, third and/or fourth processes, may be transferred to the other of the load lock chambers 111 and 112 for exiting the cluster tool 110.

FIG. 1B is a schematic diagram of in the auxiliary chamber 118 of the semiconductor fabrication apparatus 100 of FIG. 1A. A cover 210 is located in the auxiliary chamber 118 and surrounding a space, and a shelf 220 is located in the space surrounded by the cover 210. The shelf 220 includes plural stages 222 stacked one over another in the cover 210. The cover 210 may have a door 210O allowing the robot arm 113R to extend into the auxiliary chamber 118. A moving mechanism 230 is operatively connected with the shelf 220 for vertically displacing the shelf 220 while the cover 210 remains stationary, such that the shelf 220 can be moved up and down inside the cover 210, for example along the direction Z. In some embodiments, the moving mechanism 230 may be a screw mechanism including a screw and a motor. In some other embodiments, the moving mechanism 230 may be any suitable vertical actuator/elevator. Thus, by moving the shelf 220 along the direction Z to laterally align one of the stages 222 to a position for the wafer transfer, the robot arm 113R can move a wafer W onto or away from said one of the stages 222. By moving the shelf 220 along the direction Z to sequentially laterally align the respective stages 222 to positions for the wafer transfer, the robot arm 113R can sequentially move plural wafers W onto or away from the stages 222. Thus, the wafers W can be moved into and out of the cover 210, thereby achieving wafer transfer.

In some embodiments, each of the stages 222 has a recess 222B1 for accommodating the wafer W and a recess 222B2 deeper than the recess 222B1. The recess 222B2 extend from a bottom of the recess 222B1 to an edge of the stage 222. With the recesses 222B1 and 222B2, the robot arm 113R can extend to a position below the wafer W on the stage 222, thereby achieving the wafer transfer. In some embodiments, the cover 210 has a transparent plate 212 over its top. For example, the transparent plate 212 has a transmittance in a range from 50% to about 99% in visible light spectrum.

FIG. 1C is a schematic diagram of the auxiliary chamber 118 of FIG. 1B with a distance sensor 310 according to some embodiments of the present disclosure. The distance sensor 310 is mounted over a wall 100W of the semiconductor fabrication apparatus 100, for example, through a fixing element (e.g., a bracket) 320. The distance sensor 310 is out of the space surrounded by the cover 210. Stated differently, the distance sensor 310 is external to the auxiliary chamber.

The distance sensor 310 can be any distance sensor operative to effectively measure distances ranging from about 100 mm to about 300 mm. For example, the distance sensor 310 is a laser distance sensor in the present embodiments. The distance sensor 310 may provide a laser beam 312L, in a direction from top to down, to a topmost one of the stages 222 (referred to as a topmost stage 222T hereinafter), through the transparent plate 212. And, the distance sensor 310 may receive a light reflected by the topmost stage 222T, through the transparent plate 212. By using the distance sensor 310, a vertical position of the topmost stage 222T (or a distance between the topmost stage 222T and the distance sensor 310) can be measured, and the vertical positions of others of the stages 222 can be inferred according to the measured vertical position of the topmost stage 222T. In some embodiments, the laser beam 312L may be in a visible light wavelength range. The laser beam 312L is provided to an edge portion of the topmost stage 222T, and not be block during wafer transfer. The measurement of the distance sensor 310 has an advantage of fast speed, high accuracy, and good stability. In some other embodiments, the distance sensor 310 can be an ultrasonic distance sensor, an infrared distance sensor, a capacitive distance sensor, or the like.

In absence of the distance sensor 310, when a height of the stage 222 is abnormal (e.g., the stage is laterally misaligned with the robot arm 113R), the robot arm 113R extending into the cover 210 may collide with the stage 222. The collision may cause wafer breakage. In some embodiments of the present disclosure, by using the distance sensor 310, the height of the stage 222 can be measured and checked before the robot arm 113R extends into the cover 210. Thus, the collision would not occur. The distance sensor 310 may also be referred to as a laser ranging sensor, a laser displacement sensor, the like, or the combination thereof in the context.

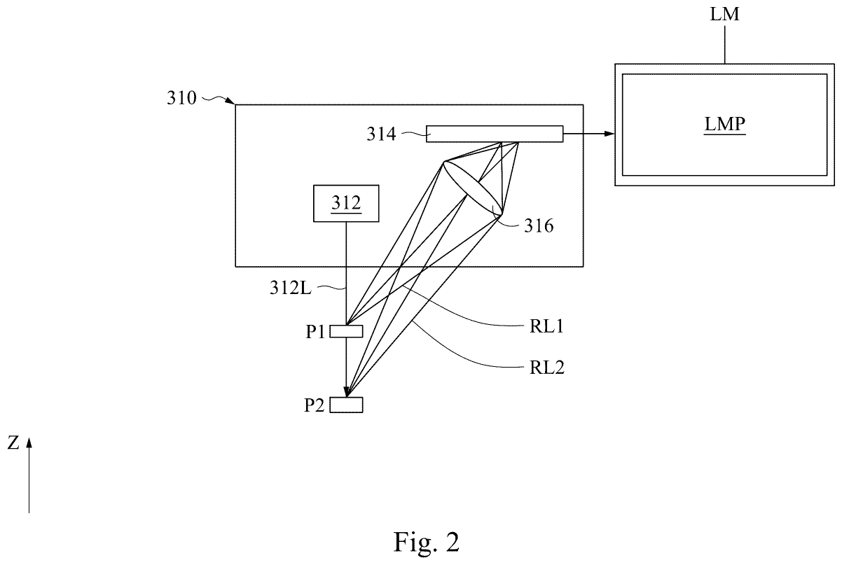

FIG. 2 is a schematic diagram of a distance sensor 310 of FIG. 1C. The distance sensor 310 may include a light emitting element 312, a light receiving element 314, and a receiver lens 316. The distance sensor 310 may be referred to as a transmitter/receiver. The light emitting element 312 may be a laser source configured to provide the laser beam 312L. The light receiving element 314 may be an image sensor, such as a complementary metal oxide semiconductor (CMOS) image sensor. The receiver lens 316 may include one or more lens optically coupled with the light receiving element 314.

To detect a target (e.g., the topmost stage 222T) at the position P1/P2, the light emitting element 312 emits a laser beam to make it reflect from the surface of the target (e.g., the topmost stage 222T), and the light receiving element 314 receives the reflected beam RL1/RL2. Based on the change in the position where the light is received (light entry angle) by the light receiving element 314, the distance sensor 310 can detect the change in the distance to the target (height or position of the target (e.g., the height or position of the topmost stage 222T)). When using this principle, the path of the laser beam 312L from the light emitting element 312 to the point of reflection on the target surface to the light receiving element 314 forms a triangle. It is called the triangulation principle (method).

A digital logic control module LM receives data from the distance sensor 310. The digital logic control module LM can determine the vertical positions of the stages 222 based on the data from the distance sensor 310. The digital logic control module LM may have one or more of input terminals for user to set the range of height deviation and detection interval for logical judgment. For example, the digital logic control module LM may include a display touch panel LMP, such that the user can set a range of height deviation and detection interval through the display touch panel LMP. In some embodiments, the digital logic control module LM is electrically connected with plural distance sensors 310 to receive data of the distance sensors 310, thereby achieving the synchronous operation of the multiple distance sensors 310, and ensuring uninterrupted operation between each other. The digital logic control module LM can also be referred to as a multifunctional module.

The digital logic control module LM may include a computer-readable storage medium and a processer coupled with the computer-readable storage medium. The computer-readable storage medium is configured to store data and processing instructions and a process coupled with the computer-readable storage medium. The processer is configured to retrieve and execute the processing instructions stored in the computer-readable storage medium. In some embodiments, the computer-readable storage medium may be a computer-readable medium, such as random access memory (RAM), read only memory (ROM), floppy disk, hard disk, flash memory or any other suitable form of digital storage. In some embodiments, the processor may be a general purpose processor, a multi-core processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor can be a microprocessor, but in the alternative, the processor can be any processor, controller, microcontroller, or state machine. A processor can also be implemented as a combination of computing devices, for example, a combination of a DSP and a microprocessor, a plurality of microprocessors, one or more microprocessors in conjunction with a DSP core, or any other such configuration. In some examples, the digital logic control module LM may be referred to as a controller.

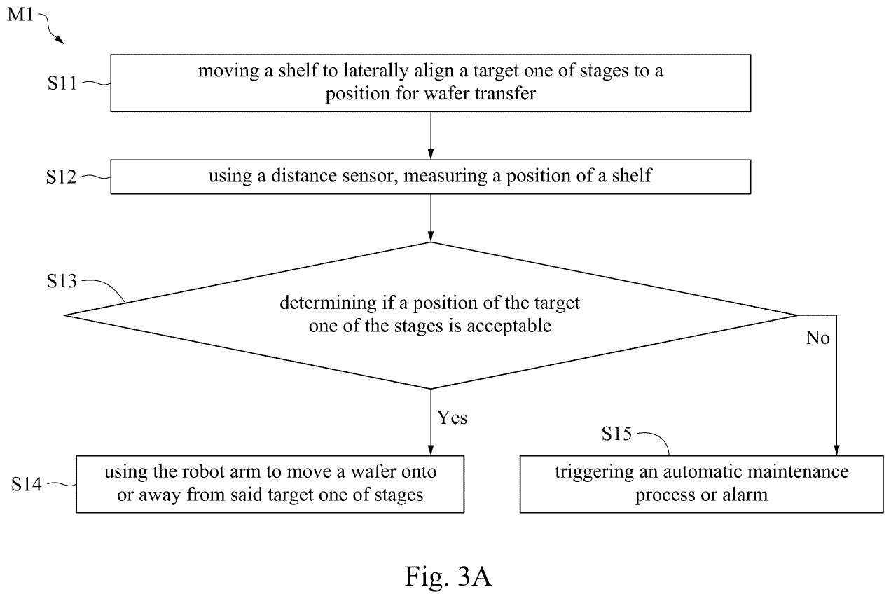

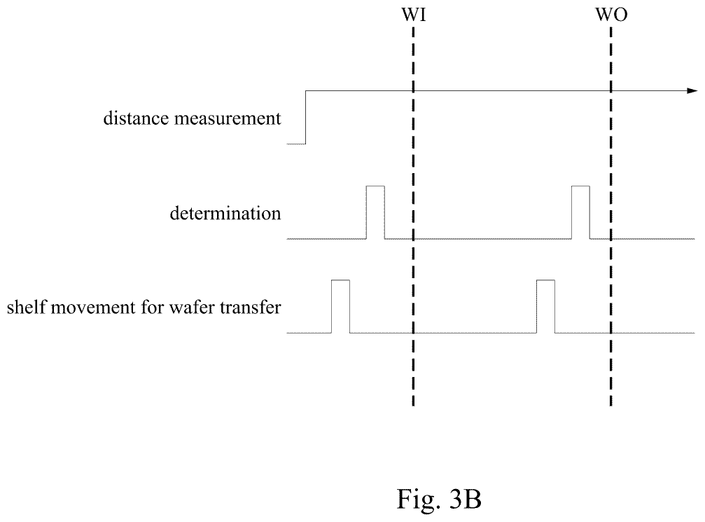

FIG. 3A is a flow chart of a method M1 for processing a wafer according to some embodiments of the present disclosure. FIG. 3B shows pulses versus time for processing a wafer according to some embodiments of the present disclosure. The method M1 includes steps S11-S15. It is understood that additional steps may be provided before, during, and after the steps S11-S15 shown in FIG. 3A, and some of the steps described below can be replaced or eliminated for additional embodiments of the method. The order of the operations/processes may be interchangeable.

In FIG. 3B, dashed bold lines WI and WO are used to indicate the timings of wafer transfer. The dashed bold line WI indicates the timing when the wafer is moved onto a target stage. And, the dashed bold line WO indicates the timing when the wafer is moved away from a target stage. In some embodiments, in regardless of the wafer W being placed on the stage 222 or not, the distance measurement on the topmost stage is kept being performed. The determination is performed just before the dashed bold lines WI and WO (or the timing before the wafer transferring process).

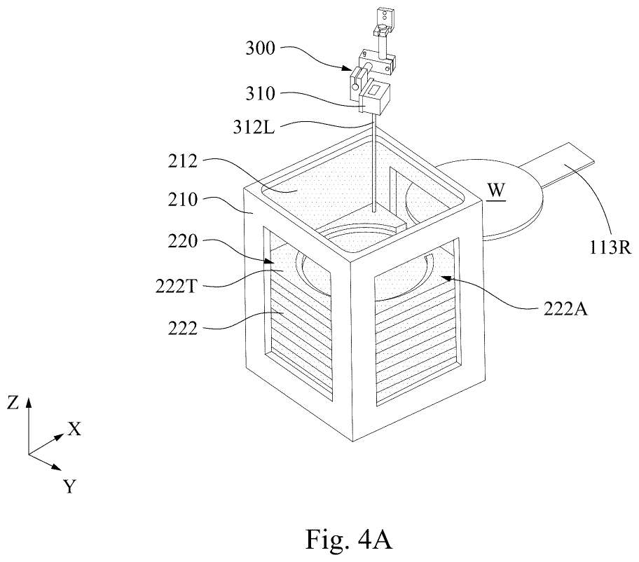

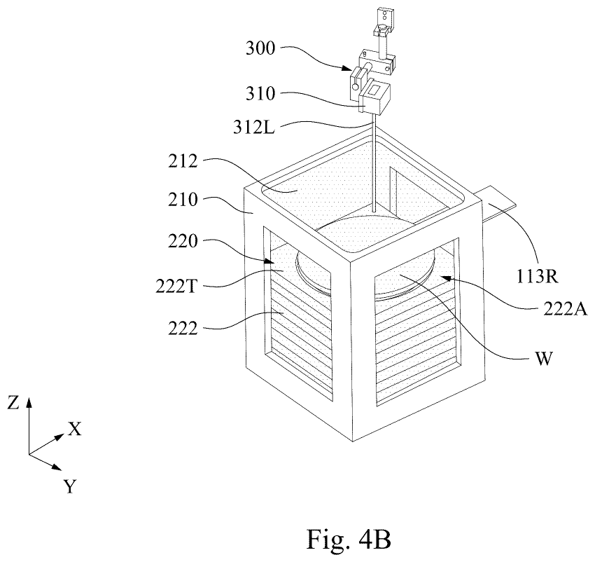

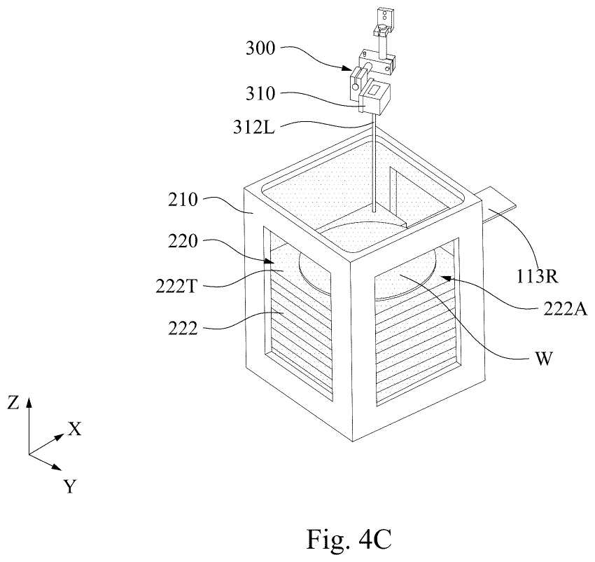

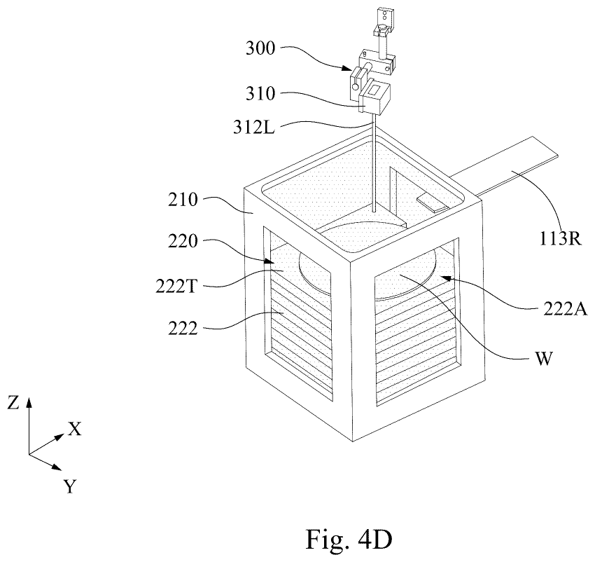

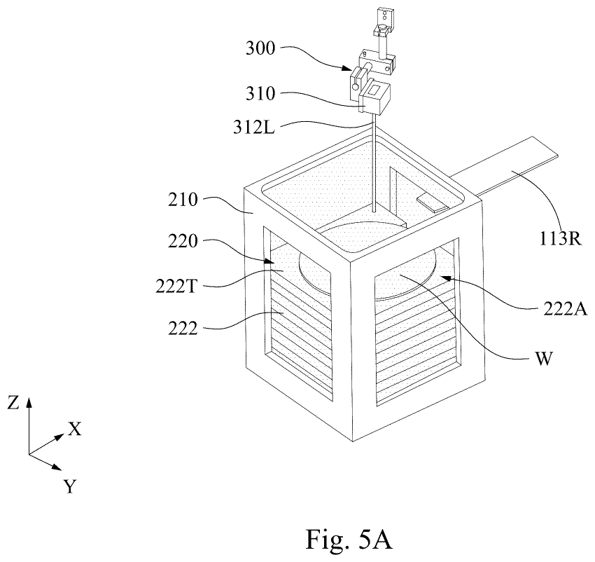

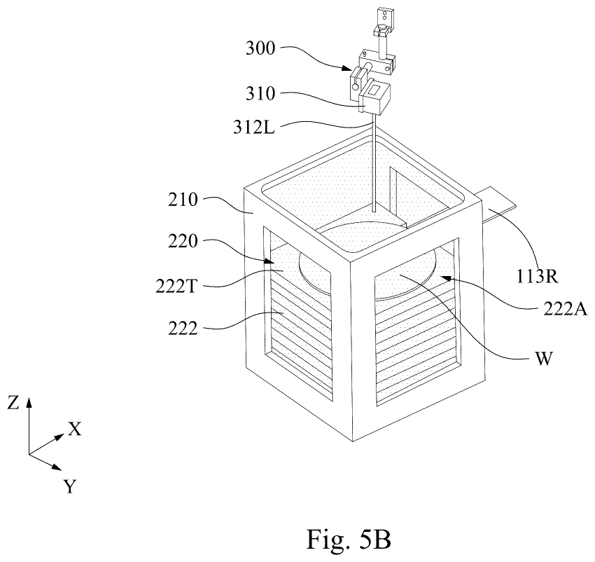

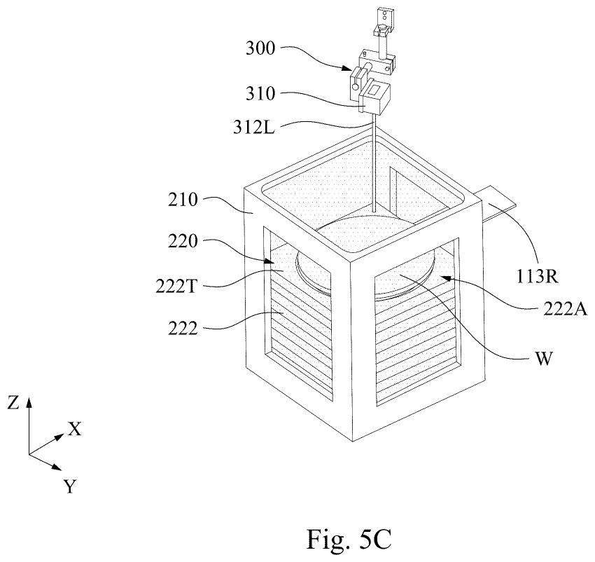

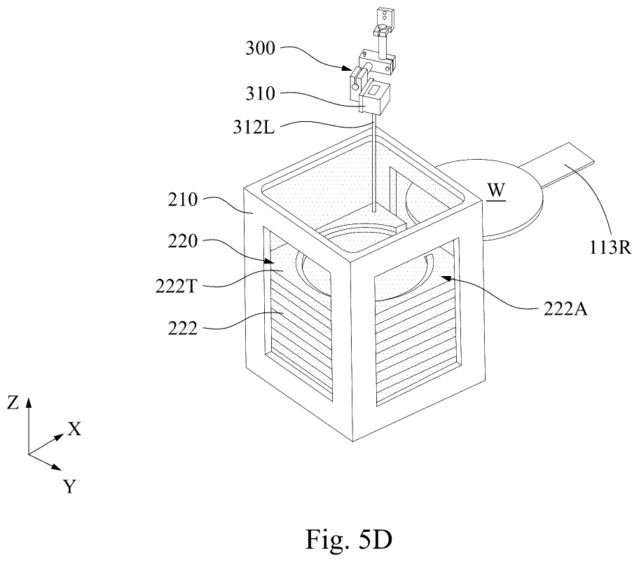

Reference is made to FIGS. 1B, 1C, 3A, and 3B. At step S11, a shelf 220 is moved vertically, for example, by the moving mechanism 230, to laterally align a target one of stage 222 (referred to as a target stage 222A in FIGS. 4A-4D and 5A-5D hereinafter) to a position for the wafer transfer, which is close to the robot arm 113R. At step S12, a distance sensor 310 is used to measure a position of a topmost stage 222T. At step S13, a determination whether the position of the target stage 222A (see FIGS. 4A-4D and 5A-5D) is acceptable is made. The determination may compare the position of the topmost stage 222T to a target level corresponding to the target stage 222A (see FIGS. 4A-4D and 5A-5D). If the difference between the position of the topmost stage 222T and the target level is less than a tolerance range, the position of the target stage 222A (see FIGS. 4A-4D and 5A-5D) is considered to be acceptable. Stated differently, if the position of the topmost stage 222T is within an acceptable range around the target level, the position of the target stage 222A (see FIGS. 4A-4D and 5A-5D) is considered to be acceptable. If the difference between the position of the topmost stage 222T and the target level is greater than a tolerance range, the position of the target stage 222A (see FIGS. 4A-4D and 5A-5D) is considered to be not acceptable. Stated differently, if the position of the topmost stage 222T is outside an acceptable range around the target level, the position of the target stage 222A (see FIGS. 4A-4D and 5A-5D) is considered to be not acceptable.

In some embodiments, the user may set a plurality of detection intervals in the digital logic control module LM as target levels respectively corresponding to the stages 222 (see FIGS. 4A-4D and 5A-5D). For example, and the determination may compare the position of the topmost stage 222T to one of the detection intervals corresponding to the target stages 222A. If the position of the topmost stage 222T is within said one of the detection intervals corresponding to the target stages 222A, the position of the target stage 222A (see FIGS. 4A-4D and 5A-5D) is considered to be acceptable. If the position of the topmost stage 222T is out of said one of the detection intervals corresponding to the target stages 222A, the position of the target stage 222A (see FIGS. 4A-4D and 5A-5D) is considered to be not acceptable.

When the determination result indicates that the position of the target stage 222A (see FIGS. 4A-4D and 5A-5D) is acceptable, the method M1 proceeds to step S14, where the robot arm 113R is used to move a wafer W onto or away from said target stage 222A (see FIGS. 4A-4D and 5A-5D), as indicated by the dashed bold lines WI and WO.

When the determination result indicates that the position of the target stage 222A (see FIGS. 4A-4D and 5A-5D) is not acceptable, the method M1 proceeds to step S15, where an automatic maintenance process and/or an alarm is triggered. In some embodiments, the automatic maintenance process may include an interlock between machines (e.g., robot arm 113R), thereby stopping the wafer transfer process. In some embodiments, triggering alarm may include sending out an alarm massage, which includes a real-time monitoring (RTM) data. An operator receives the alarm message may perform a maintenance process (e.g., stopping the machine) for recovering the position of the topmost stage 222T.

In some embodiments, the digital logic control module LM may be electrically coupled with a controller of the robot arm 113R and the moving mechanism 230 (referring to FIG. 1B) that moves the shelf 220 up and down. Thus, the digital logic control module LM can perform the steps S11-S15 in FIG. 3A.

FIGS. 4A-4D illustrate an example of moving the wafer W onto a target stage in accordance with some embodiments of the present disclosure. In the example of FIGS. 4A-4D, the target stage 222A is the topmost stage 222T. In some alternative examples, the target stage 222A can be any one of the stages 222 below the topmost stage 222T. In FIG. 4A, the robot arm 113R carries a wafer W. Before a wafer W is loaded onto the target stage 222A, the shelf 220 is moved to lateral align the target stage 222A to a position for the wafer transfer, which is close to the robot arm 113R (e.g., step S11), and the distance sensor 310 is used to measure a position of the shelf 220 (e.g., the topmost stage 222T (e.g., step S12)). If the determination (e.g., step S13) is made to show the position of the target stage 222A is considered to be acceptable, the wafer W is moved onto the target stage 222A by the robot arm 113R (e.g., step S14), as the steps shown in FIGS. 4B-4D in a sequence. For example, in FIG. 4B, the robot arm 113R may extend into the cover 210 and move the wafer W to a position just above the target stage 222A. In FIG. 4C, the shelf 220 may move upward, such that the target stage 222A can receive the wafer W from the robot arm 113R. In FIG. 4D, the robot arm 113R may move away from the cover 210. Alternatively, if the determination (e.g., step S13) is made to show the position of the target stage 222A is considered to be not acceptable, the robot arm 113R carrying the wafer W would stop from reaching the target stage 222A (e.g., step S15).

FIGS. 5A-5D illustrate an example of moving the wafer W away from a target stage in accordance with some embodiments of the present disclosure. In the example of FIGS. 4A-4D, the target stage 222A is the topmost stage 222T. In some alternative examples, the target stage 222A can be any one of the stages 222 below the topmost stage 222T. In FIG. 5A, the target stage 222T carries a wafer W. Before a wafer W is unloaded from the target stage 222T, the shelf 220 is moved to align the target stage 222A to a position for the wafer transfer, which is close to the robot arm 113R (e.g., step S11), and the distance sensor 310 is used to measure a position of the shelf 220 (e.g., the topmost stage 222T (e.g., step S12)). If the determination (e.g., step S13) is made to show the position of the target stage 222A is considered to be acceptable, the wafer W is moved away from the target stage 222A by the robot arm 113R (e.g., step S14), as the steps shown in FIGS. 5B-5D in a sequence. For example, in FIG. 5B, the robot arm 113R may extend into the cover 210 to a position below the wafer W and above the target stage 222A. In FIG. 5C, the shelf 220 may move downward, such that the robot arm 113R lifts up the wafer W from the target stage 222A. In FIG. 5D, the robot arm 113R carries the wafer W and moves away from the cover 210. Alternatively, if the determination (e.g., step S13) is made to show the position of the target stage 222A is considered to be not acceptable, the robot arm 113R would stop from reaching the wafer W on the target stage 222A (e.g., step S15).

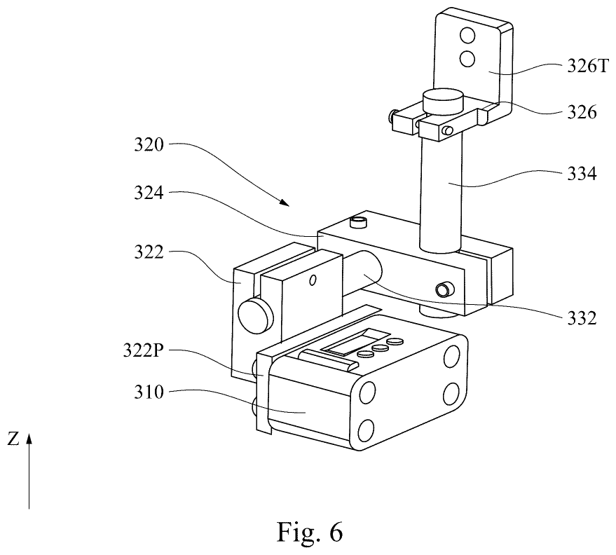

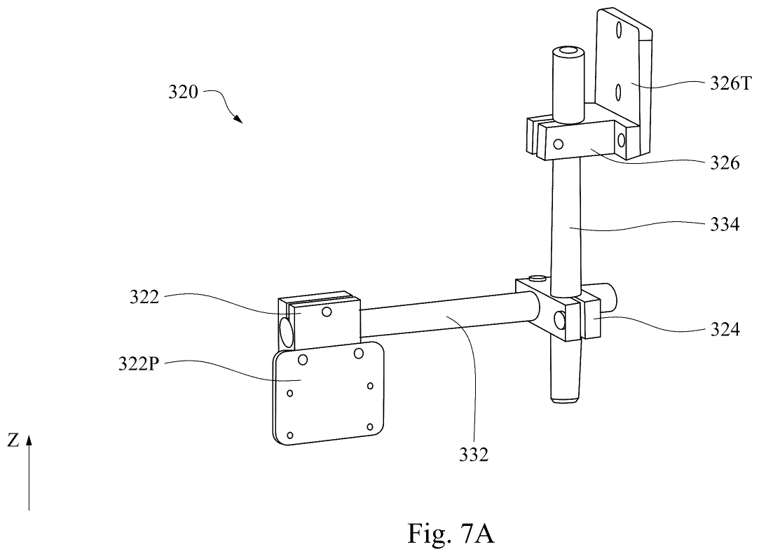

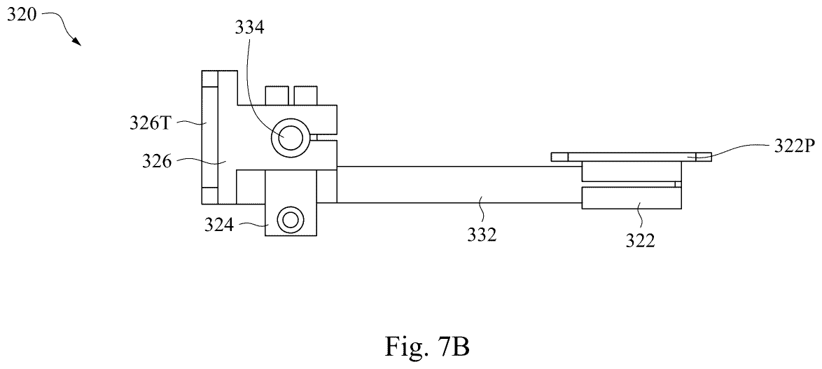

FIG. 6 is a perspective view of a distance sensor 310 held by a fixing element 320 according to some embodiments of the present disclosure. FIG. 7A is a schematic diagram of a fixing element 320 of FIG. 6. FIG. 7B is a cross-sectional view of a fixing element 320 of FIG. 6. The fixing element 320 has plural fixed blocks 322, 324, and 326 and adjusting levers 332 and 334. The fixed block 322 may have a plate for holding the distance sensor 310. The fixed block 326 may have a fixing component 322F (e.g., holes) for being fixed with the wall 100W of the semiconductor fabrication apparatus 100 (referring to FIG. 1C). The adjusting lever 332 may connect the fixed block 322 to the fixed block 324, and the adjusting lever 334 may connect the fixed block 324 to the fixed block 326. By adjusting the lengths of the adjusting levers 332 and 334, a position of the distance sensor 310 can be adjusted.

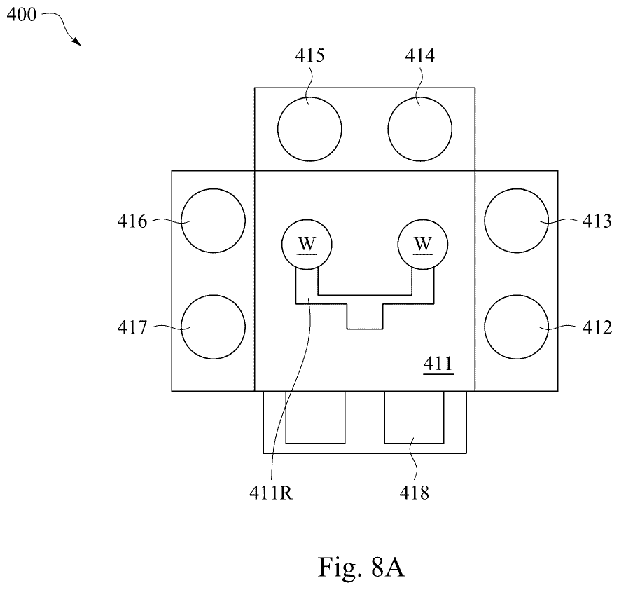

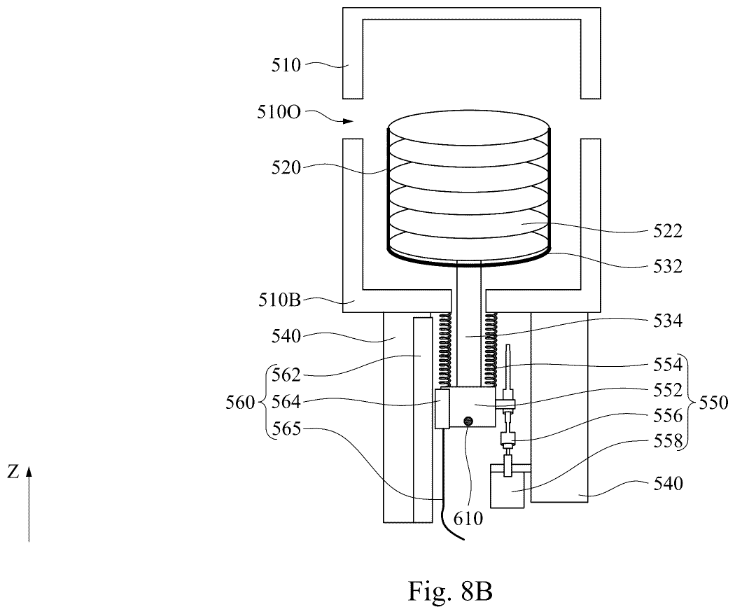

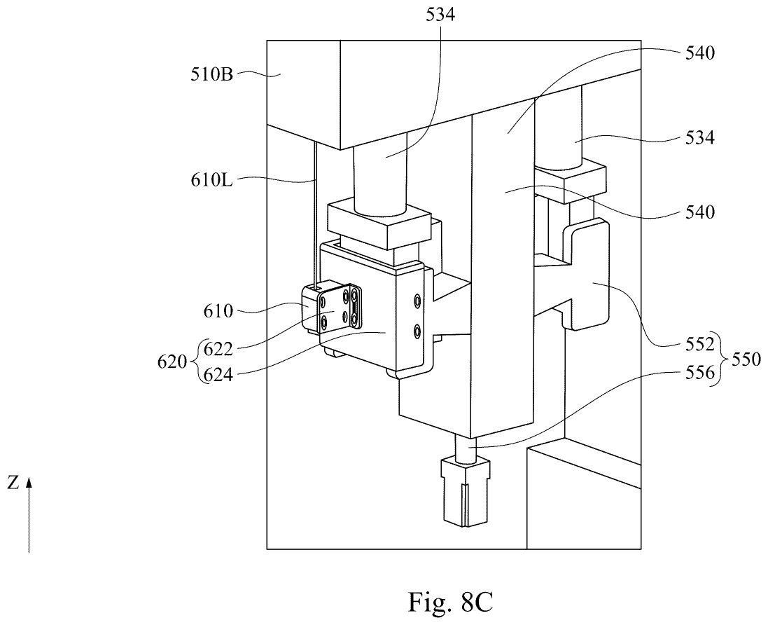

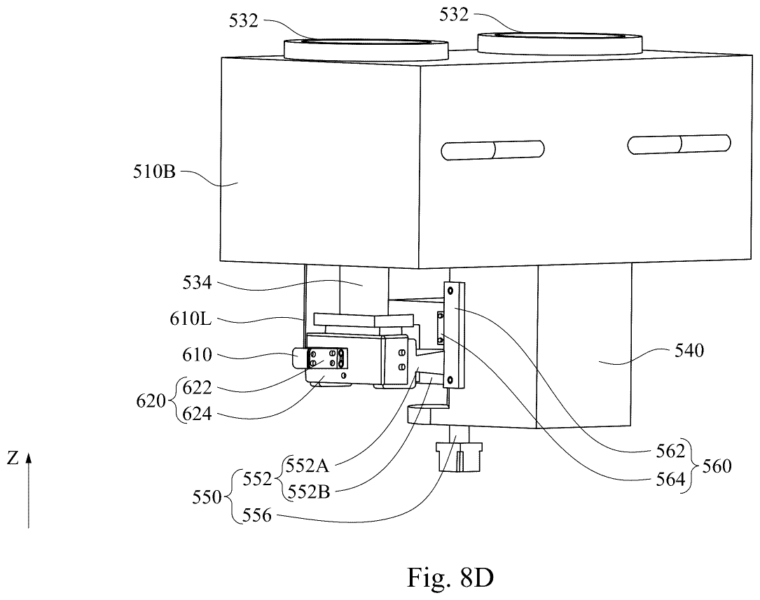

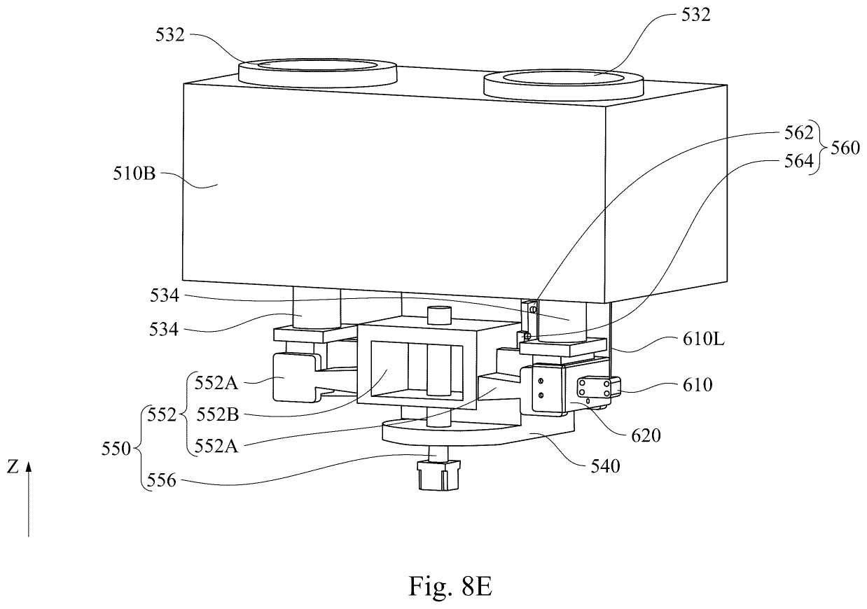

FIG. 8A is a schematic diagram of a semiconductor fabrication apparatus 400 according to some embodiments of the present disclosure. The semiconductor fabrication apparatus 400 includes a cluster tool, including a wafer handling chamber 411 and plural chambers 412-417. In some embodiments, the chambers 412-415 are processing chambers, and the chamber 416 and 417 are auxiliary chambers. The cluster tool may also include other chambers in some other embodiments. For example, the cluster tool may also include load lock chambers 418 for transferring wafers W into and out of the cluster tool, respectively. In various embodiments, the cluster tool (including the wafer handling chamber 411 and the chambers 412-417) is under vacuum, and the load lock chambers 418 may “pump down” the wafers W introduced into the cluster tool (e.g., by way of the vacuum system). In some embodiments, the load lock chambers 418 may be adapted to receive and release a single wafer or a plurality of wafers (e.g., loaded into a cassette). By way of example, the load lock chambers 418 may be separated from the wafer handling chamber 411 by way of a gate valve, allowing the wafer handling chamber 411 to remain under vacuum when one or both of the load lock chambers 418 are vented.

The wafer handling chamber 411 may also be referred to as a buffer chamber. In various embodiments, the wafer handling chamber 411 is equipped with a transfer arm 411R (e.g., robotic transfer arm). The transfer arm 411R may automatically move smoothly along any of a horizontal and/or vertical axis, so as to transfer wafers/substrates W between any two of the load lock chambers 418 and the chambers 412-417.

The processing chambers 412-417 may be configured to perform a number of substrate processing operations, such as atomic layer deposition (ALD), chemical vapor deposition (CVD), physical vapor deposition (PVD), etching, film coating, pre-treatment/pre-soak, de-gassing, as well as annealing, and/or other suitable processing or operations in front-end-of-line (FEOL) or back-end-of-line (BEOL) process. For example, one or more of the processing chambers 412-417 may be configured to deposit various dielectric layers and metal layers (e.g., TiN layer, AlCu layer, or the like), coat an anti-reflection layer, thermally pre-treat the wafers W, and/or other suitable processing or operations. In various embodiments, the cluster tool may have more or less processing chambers, for example, for a desired process to be performed by the cluster tool.

The auxiliary chambers 416 and 417 may temporally keep the wafers W before, during, or after the processes of the processing chambers 412-415. In some embodiments, the auxiliary chambers 416 and 417 may be equipped with a cooling system for cooling down the wafers W, and the auxiliary chambers 416 and 417 may be referred to as cool-down chambers.

FIG. 8B is a cross-sectional view of an auxiliary chamber 416/417 of the semiconductor fabrication apparatus 400 of FIG. 8A according to some embodiments of the present disclosure. The auxiliary chamber 416/417 (referring to FIG. 8A) includes a chamber wall 510 defining a chamber interior. The auxiliary chamber 416/417 may include a shelf 520, a platform 532 supporting the shelf 520, a lift shaft 534 supporting the platform 532. The shelf 520 includes plural stages 522 stacked one over another in the chamber interior defined the chamber wall 510. The stages 522 may respectively support wafers. The chamber wall 510 may have a slot 510O, which allows a robot arm 411R to extend into the chamber interior accessing the wafers on the stages 522 of the shelf 520, thereby achieving wafer transfer. The lift shaft 534 extends in the direction Z.

A moving mechanism 550 is fixed on a wall 540 below a bottom 510B of the chamber wall 510. The moving mechanism 550 is operatively connected with the lift shaft 534 for vertically displacing the shelf 520. In the present embodiments, the moving mechanism 550 can be a screw mechanism. For example, the movement mechanism 500 may have a base 552, a spring 554, a rotation screw 556, and a shaft elevation motor 558. The base 552 is separated/disconnected from the wall 540 and engaged with a bottom of the lift shaft 534. According to some embodiments, a power supply and controller may supply power to trigger the shaft elevation motor 558 based on commands to lift the platform 532 from the controller, thereby spinning the rotation screw 556. The rotation screw 556 is engaged with the base 552 and the wall 540. By rotating the rotation screw 556, the spiral motion is converted into the vertical motion, thereby raising and/or lowering the base 552 and the lift shaft 534 engaged with the base 552. The spring 554 is coupled between a top of the base 552 and a bottom 510B of the chamber wall 510, thereby relaxing the force of the vertical motion. In some other embodiments, the moving mechanism 550 may be any suitable vertical actuator/elevator.

An encoder 560 can be a sensing device configured to provide a recipe of a vertical motion for the shaft elevation motor 558 and measure the vertical motion. For example, the encoder 560 has a first portion 562, a second portion 564, and a wire 565 electrically connected with the second portion 564. The encoder 560 can convert a vertical motion to an electrical signal that can be read by some type of control device in a motion control system, for example, through the wire 565.

FIG. 8C is a schematic diagram illustrating a first exemplary configuration of various configurations of FIG. 8B. Reference is made to FIGS. 8B and 8C. A distance sensor 610 is mounted on the base 552, for example, through a fixing element 620. The distance sensor 610 is out of the chamber interior defined by the chamber wall 510. Stated differently, the distance sensor 610 is external to the chamber. By rotating the rotation screw 556, the distance sensor 610 is lifted up and downward along with the lift shaft 534 and the platform 532 supported by the lift shaft 534. In the present embodiments, the distance sensor 610 may be a laser distance sensor providing a laser beam 610L, in a direction from bottom to top (e.g., along the direction Z), to the bottom 510B of the chamber wall 510, and the distance sensor 610 may receive a light reflected by the bottom 510B of the chamber wall 510. By using the distance sensor 610, a vertical position of the base 552 (or a vertical distance between the distance sensor 610 and the bottom 510B of the chamber wall 510) can be measured, such that a vertical position of the platform 532 can be determined, and the vertical positions of the stages 522 can be inferred according to the determined vertical position of the platform 532. In some embodiments, the laser beam 610L may be in a visible light wavelength range. The measurement has an advantage of fast speed, high accuracy, and good stability. In some other embodiments, the distance sensor 610 can be an ultrasonic distance sensor, an infrared distance sensor, a capacitive distance sensor, or the like. Other details of the distance sensor 610 are similar to those illustrated of the distance sensor 310 in FIG. 2, and thereto not repeated herein. With the distance sensor 610, the method M1 in FIGS. 3A and 3B can also be performed using the semiconductor fabrication apparatus 400.

FIGS. 8D and 8E are schematic diagrams illustrating a second exemplary configuration of various configurations of FIG. 8B. Reference is made to FIGS. 8B, 8D and 8E. In the present embodiments, two platform 532 of two auxiliary chambers (e.g., the auxiliary chambers 416/417 in FIG. 8A) share a moving mechanism 550. For example, the moving mechanism 550 is operatively connected with two lift shafts 534 respectively supporting the two platforms 532 for vertically displacing the platforms 532. For example, the movement mechanism 500 may have a base 552 and a rotation screw 556. The base 552 is separated/disconnected from the wall 540 and engaged with bottom of the two lift shafts 534. A power supply and controller may supply power to trigger the shaft elevation motor 558 (referring to FIG. 8B) based on commands to lift the platform 532 from the controller, thereby spinning the rotation screw 556. The rotation screw 556 is engaged with the base 552 and the wall 540. By rotating the rotation screw 556, the spiral motion is converted into the vertical motion, thereby raising and/or lowering the base 552 and the lift shaft 534 engaged with the base 552. For example, the base 552 has two first portions 552A respectively engaged with the lift shafts 534 and a second portion 552B engaged with the rotation screw 556, in which the two first portions 552A are fixed to two ends of the second portion 552B, respectively.

The encoder 560 has a first portion 562 fixed on the wall 540 and a second portion 564 fixed on the base 552 of the movement mechanism 500. Thus, when the base 552 and the lift shaft 534 are raised or lowered, the encoder 560 can be measure the vertical motion between the first portion 562 and the second portion 564, and convert the vertical motion to an electrical signal that can be read by some type of control device in a motion control system.

As illustrated previously, a distance sensor 610 is mounted on the base 552, for example, through a fixing element 620. By rotating the rotation screw 556, the distance sensor 610 is lifted up and downward along with the lift shaft 534 and the platform 532 supported by the lift shaft 534. In the present embodiments, the distance sensor 610 may be a laser distance sensor providing a laser beam 610L, in a direction from bottom to top (e.g., along the direction Z), to the bottom 510B of the chamber wall 510, and the distance sensor 610 may receive a light reflected by the bottom 510B of the chamber wall 510. By using the distance sensor 610, a vertical position of the base 552 (or a vertical distance between the distance sensor 610 and the bottom 510B of the chamber wall 510) can be measured, such that a vertical position of the platform 532 can be determined, and the vertical positions of the stages 522 can be inferred according to the determined vertical position of the platform 532. Other details of the present embodiments are similar to those illustrated in the embodiments of FIGS. 8B and 8C, and thereto not repeated herein.

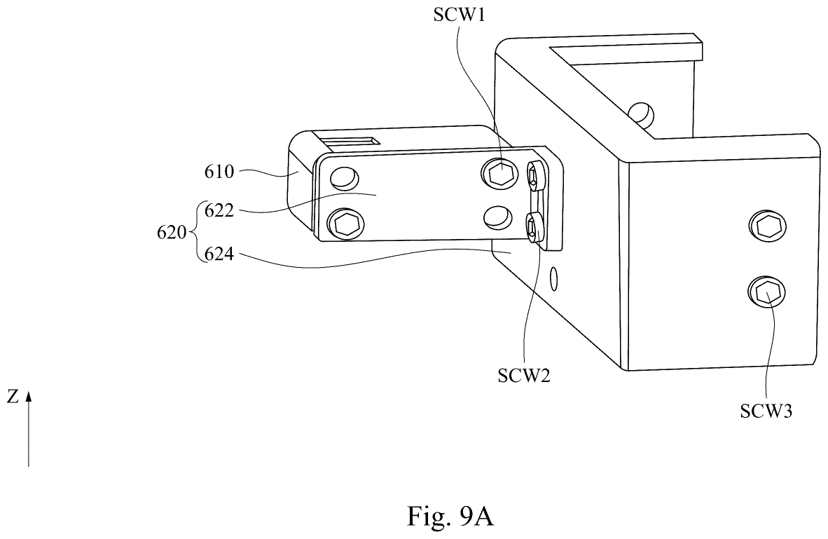

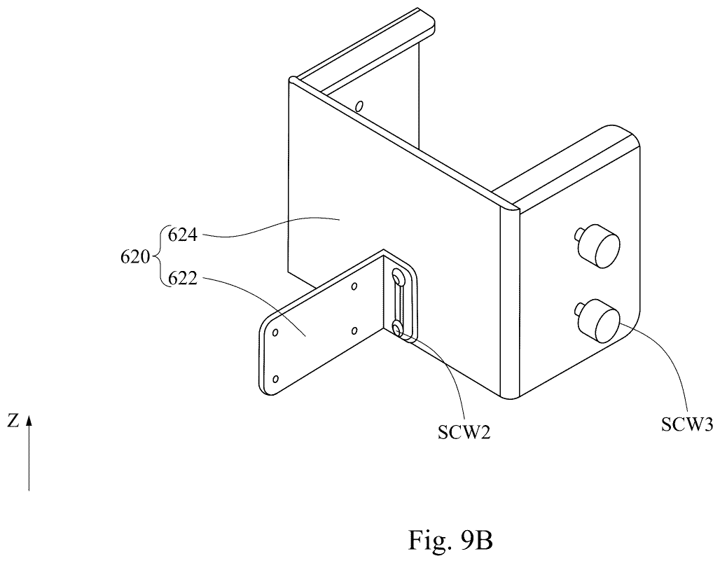

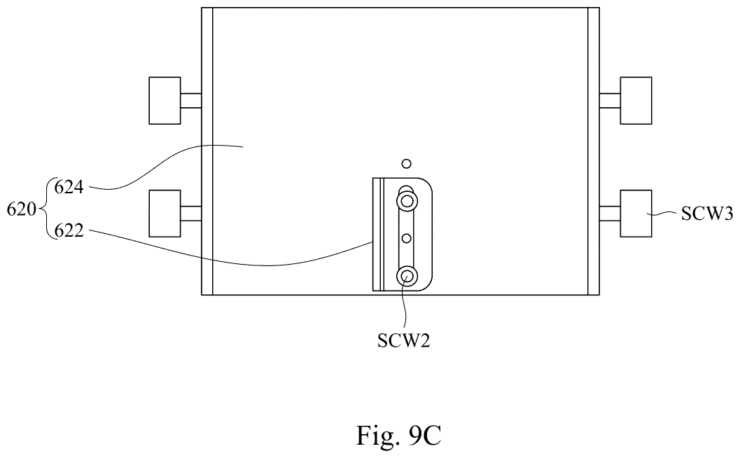

FIG. 9A is a perspective view of a distance sensor 610 held by a fixing element 620 according to some embodiments of the present disclosure. FIG. 9B is a schematic diagram of the fixing element 620 of FIG. 9A. FIG. 9C is a cross-sectional view of the fixing element 620 of FIG. 9A. In some embodiments, the fixing element 620 has a bracket 622 and a bracket 624. In some embodiments, the distance sensor 610 can be fixed on the bracket 622 by screws SCW1, and the bracket 622 can be fixed on the bracket 624 by screws SCW2. In some embodiments, the bracket 624 can be fixed on the base 552 (referring to FIGS. 8B and 8C) by screws SCW3. The position of the distance sensor 610 can be slightly adjusted by the fixing element 620.

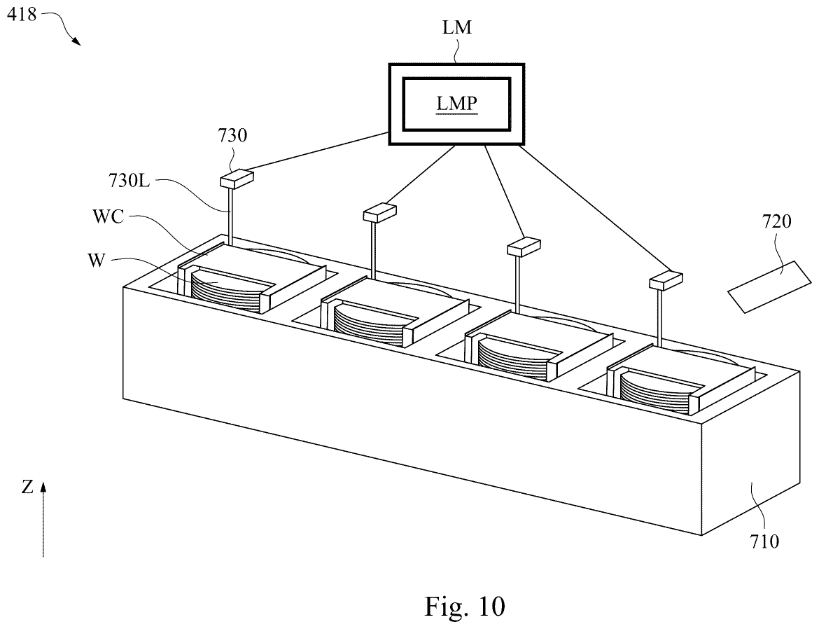

FIG. 10 is a schematic diagram of a load lock chamber 418 of the semiconductor fabrication apparatus 400 of FIG. 8A. In some embodiments, the load lock chamber 418 may have one or more platforms 710 for supporting one or more wafer cassettes WC. Each of the wafer cassettes WC may hold plural wafers W. The load lock chamber 418 may include one or more distance sensors 730. In the present embodiments, each of the distance sensors 730 may be a laser distance sensor configured to provide a laser beam 730L onto each of the wafer cassettes WC and detects a beam reflected by said wafer cassettes WC. When a result of the detection indicates the wafer cassette WC is correctly placed on the platform 710, a robot arm 411R may be configured to move a wafer W onto or away from the wafer cassettes WC, thereby achieving the wafer transfer process. In some other embodiments, the distance sensors 730 can be ultrasonic distance sensors, an infrared distance sensors, capacitive distance sensors, or the like. Other details of the distance sensor 730 are similar to those illustrated of the distance sensor 310 in FIG. 2, and thereto not repeated herein.

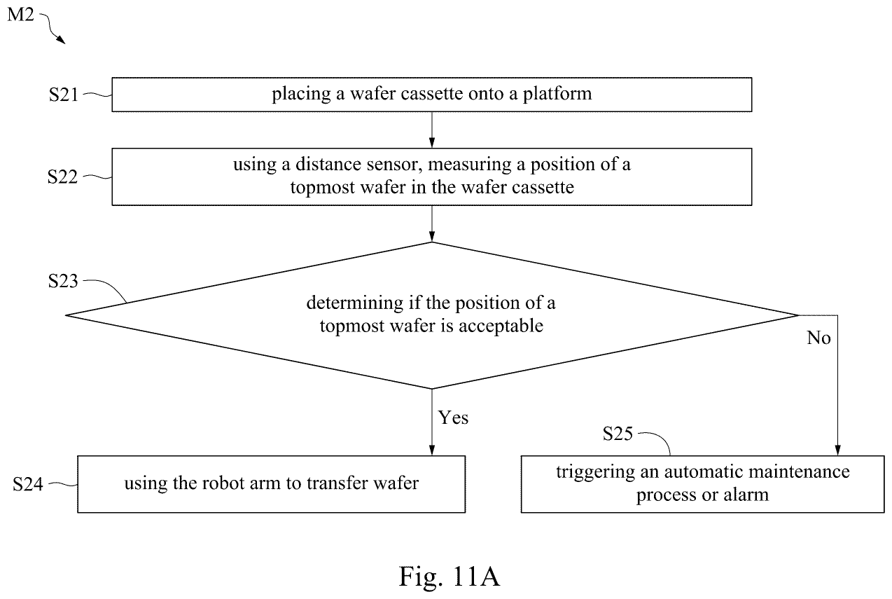

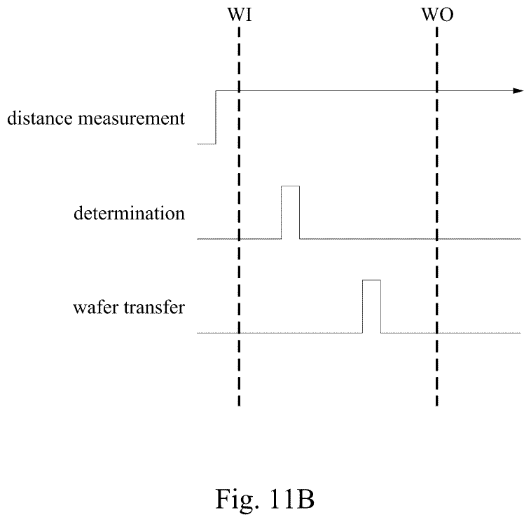

FIG. 11A is a flow chart of a method M2 for processing a wafer according to some embodiments of the present disclosure. FIG. 11B shows pulses versus time for processing a wafer according to some embodiments of the present disclosure. The method M2 includes steps S21-S25. It is understood that additional steps may be provided before, during, and after the steps S21-S25 shown in FIG. 11A, and some of the steps described below can be replaced or eliminated for additional embodiments of the method. The order of the operations/processes may be interchangeable.

In FIG. 11B, the dashed bold line WI indicates the timing when the wafer cassette WC is moved onto the platform 710, and the dashed bold line WO indicates the timing when the wafer cassette WC is moved away from the platform 710. In some embodiments, in regardless of the wafer cassette WC being placed on the platform 710 or not, the distance measurement is kept being performed. The wafer transfer process is performed during the time interval between the dashed bold lines WI and WO.

Reference is made to FIG. 10, FIG. 11A, and FIG. 11B. At step S21, a wafer cassette WC is placed onto a platform 710 of the load lock chamber 418. At step S22, a distance sensor 730 is used to measure a position of a topmost wafer W in the wafer cassette WC. By using the distance sensors 730 and the digital logic control module LM, the height of all wafers W in the lots can be detected and determined. At step S23, a determination whether the position of a topmost wafer is acceptable is made. At step S23, the determination may compare the position of the topmost wafer to a previous value of a position of a topmost wafer measured previously (or a theoretical range). If the difference between the position of the topmost wafer and the previous value is less than an acceptable value (or if the position of the topmost wafer is within the theoretical range), the wafer cassette WC is considered to be correctly placed on the platform 710, and the method M2 proceeds to step S24, a wafer transferring process is performed, for example, through the robot arm 720. If the difference between the position of the topmost wafer and the previous value is greater than an acceptable value (or if the position of the topmost wafer is outside the theoretical range), the wafer cassette WC is considered to be wrongly placed on the platform 710, and the method M2 proceeds to step S25, an automatic maintenance process and/or an alarm is triggered.

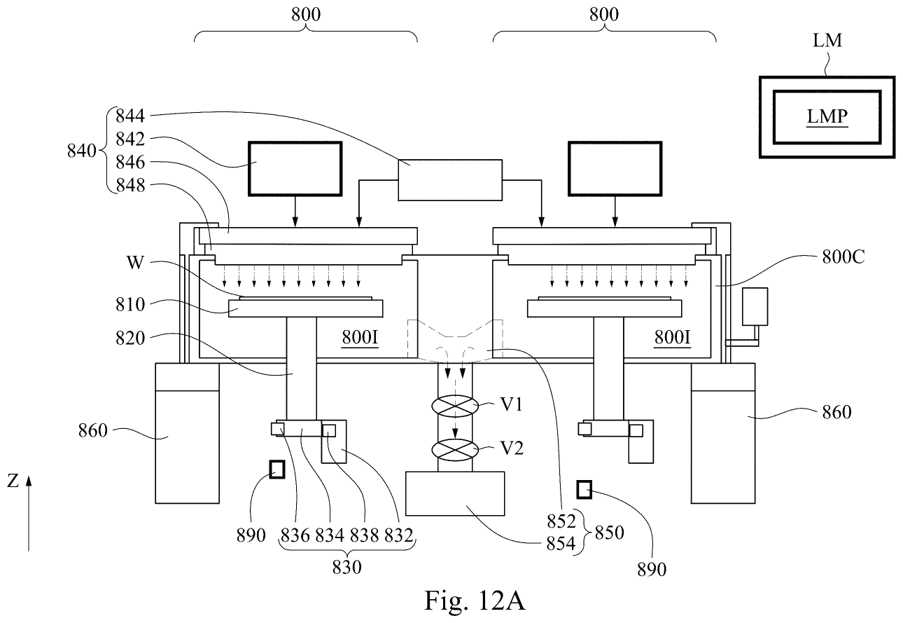

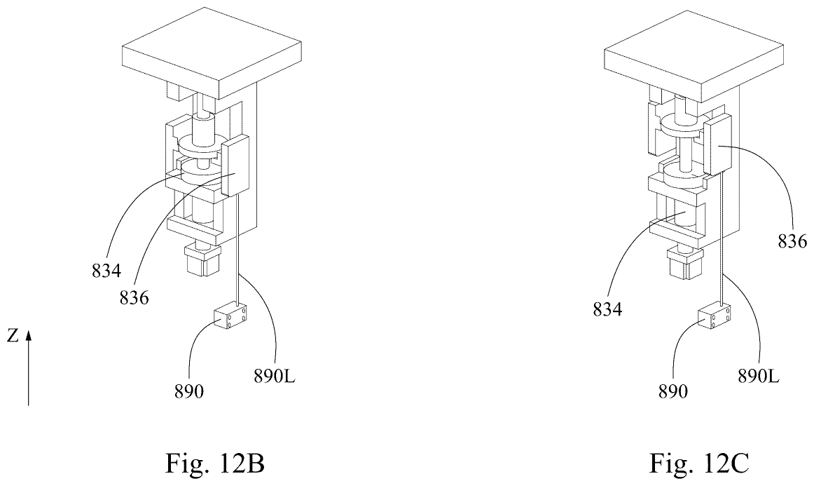

FIG. 12A is a schematic diagram of process chambers 800 of a semiconductor fabrication apparatus according to some embodiments of the present disclosure. FIGS. 12B and 12C are schematic diagram of a motor and a distance sensor of a process chamber of the semiconductor fabrication apparatus of FIG. 12A. Each of the process chambers 800 may be any one of the chambers 412-417 in FIG. 8A. The process chambers 800 may include a wafer platform 810, a shaft 820, a moving mechanism 830, a gas supply system 840, a gas exhaust system 850, a radio-frequency (RF) generator 860, and a distance sensor 890. The wafer platform 810 is configured to carry a wafer W. In some embodiments, the wafer platform 810 may include a heater for heating the wafer W. The shaft 820 is configured to support the wafer platform 810.

In the present embodiments, the moving mechanism 830 can be a screw mechanism. For example, the moving mechanism 830 may include a motor 832 and a lead screw 834 connected with the shaft 820. The motor 832 can provide rotational motion to the lead screw 834, and the lead screw 834 can convert rotational motion into linear motion. As a result the shaft 820 connected with the lead screw 834 can be moved up and down by the motor 832 and the lead screw 834, thereby moving the wafer platform 810 upward and downward. In some other embodiments, the moving mechanism 830 may be any suitable vertical actuator/elevators.

The process chambers 800 may has a chamber cover 800C surrounding a chamber interior 800I, in which the wafer platform 810 is inside the chamber interior 800I, and the shaft 820, the moving mechanism 830, the gas supply system 840, the gas exhaust system 850, the RF generator 860, and the distance sensor 890 are outside the chamber interior 800I.

The gas supply system 840 is configured to provide a process gas to the chamber interior 800I, thereby achieving the deposition and/or etching process. For example, the gas supply system 840 may include a process gas source 842, a clean gas source 844, a gas box 846, and a shower plate 848. The process gas source 842 and the clean gas source 844 stores one or more process gas and one or more clean gas, respectively. The gas box 846 is fluidly coupled with the process gas source 842 and the clean gas source 844, and distribute the process gas and/or the clean gas through the shower plate 848. The gas exhaust system 850 may be configured to remove the process gas and/or the clean gas from the chamber interior 800I and adjust a pressure in the chamber interior 800I. For example, the gas exhaust system 850 include exhaust pipes 852, a vacuum source 854 fluidly coupled with the chamber interior 800I through the exhaust pipes 852, and an isolation valve V1 and a throttle valve V2 may be fluidly connected with the exhaust pipes 852. The RF generator 860 is configured to generate and/or adjust a plasma in the chamber interior 800I.

In some embodiments, the distance sensor 890 is fixed at a same position when the wafer platform 810 is moved upward and downward. And, the moving mechanism 830 mounted on the shaft 820 would move upward and downward when the wafer platform 810 is moved upward and downward.

In the present embodiments, the distance sensor 890 may be a laser distance sensor configured to provide a laser beam 890L onto a component 836 of the moving mechanism 830 and detects a beam reflected by the component 836 of the moving mechanism 830. When a result of the detection indicates the wafer W is correctly placed on the wafer platform 810, a robot arm 411R (referring to FIG. 8A) may be configured to move a wafer W onto or away from the wafer platform 810, thereby achieving the wafer transfer process. In some other embodiments, the distance sensor 890 can be an ultrasonic distance sensor, an infrared distance sensor, a capacitive distance sensor, or the like. Other details of the distance sensor 890 are similar to those illustrated of the distance sensor 310 in FIG. 2, and thereto not repeated herein.

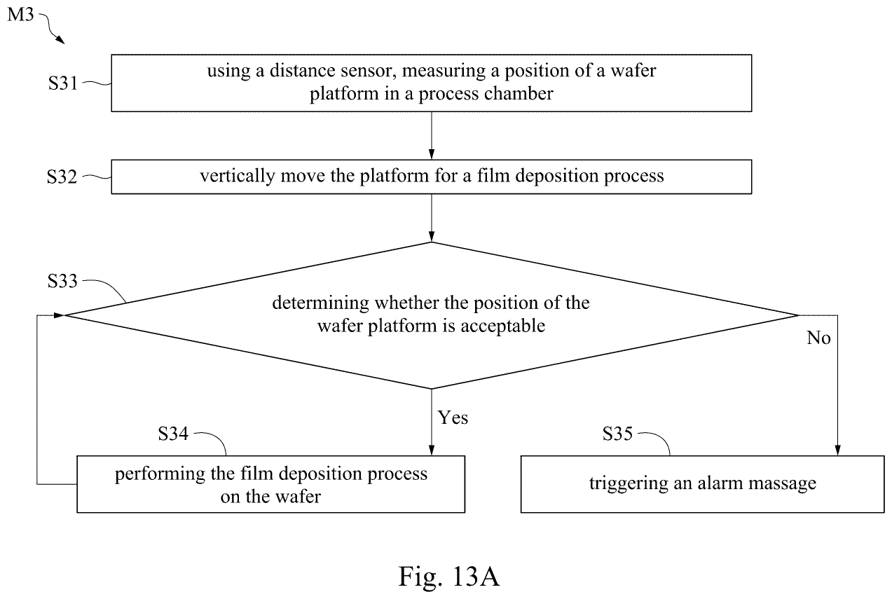

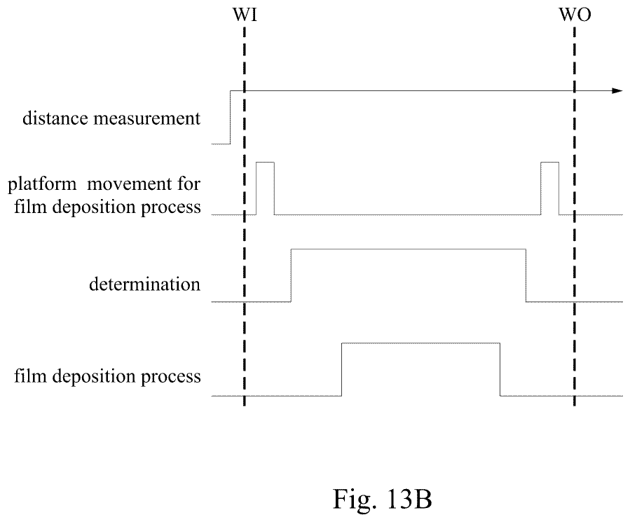

FIG. 13A is a flow chart of a method for processing a wafer according to some embodiments of the present disclosure. FIG. 13B shows pulses versus time for processing a wafer according to some embodiments of the present disclosure. The method M3 includes steps S31-S35. It is understood that additional steps may be provided before, during, and after the steps S31-S35 shown in FIG. 13A, and some of the steps described below can be replaced or eliminated for additional embodiments of the method. The order of the operations/processes may be interchangeable.

In FIG. 13B, dashed bold lines WI and WO are used to indicate the timings of wafer transfer. The dashed bold line WI indicates the timing when the wafer is moved onto the platform 810. And, the dashed bold line WO indicates the timing when the wafer is moved away from the platform 810. In some embodiments, in regardless of the wafer W being placed on the stage 222 or not, the distance measurement is kept being performed. The film deposition process is performed during the time interval between the dashed bold lines WI and WO.

Reference is made to FIG. 12A, FIG. 13A, and FIG. 13B. At step S31, a distance sensor 890 is used to measure a position of a wafer platform 810 in a chamber interior 800I. By using the distance sensors 890 and the digital logic control module LM, a vertical shift of the moving mechanism 830 can be measured, thereby determining the position of the wafer platform 810 in the chamber interior 800I. The distance sensor 890 is external to the chamber 800.

At step S32, after the wafer is moved onto the platform 810, the wafer platform 810 is vertically moved for a film deposition process with a suitable film thickness. In some embodiments, the wafer platform 810 may be moved vertically from a first level laterally aligned with a chamber slot, which a robot arm may extend through for wafer transfer, to a second level for film deposition process with a suitable film thickness. In some examples, the first level is lower than the second level. Alternatively, in some other examples, the first level is higher than the second level. In some embodiments of the present disclosure, the thickness of the deposited film is affected by a gap between the wafer platform 810 and the shower plate 848, and the vertical movement of the wafer platform 810 is controlled by an encoder 838 on the motor 832.

At step S33, after vertically moving the wafer platform 810, a determination whether the position of the wafer platform 810 is acceptable is made. At step S33, the determination may compare the position of the wafer platform 810 to a theoretical range (e.g., a recipe provided by the encoder 838). If the position of the wafer platform 810 is within the theoretical range, the position of the wafer platform 810 is considered to be correct, and the method M3 proceeds to step S34. At step S34, a semiconductor process is performed on the wafer W. For example, the semiconductor process may include depositing and/or etching a film material layer on the wafer W. The determination and the height detection process (e.g., the step of measuring the position of a wafer platform 810 in the process chamber 800) may be performed in real-time during the semiconductor process. After the semiconductor process, the wafer platform 810 may be moved vertically from the second level for film deposition process to the first level laterally aligned with the chamber slot for wafer transfer. If the position of the wafer platform 810 is outside the theoretical range, the position of the wafer platform 810 is considered to be wrong, and the method M3 proceeds to step S35, an alarm massage is sent out.

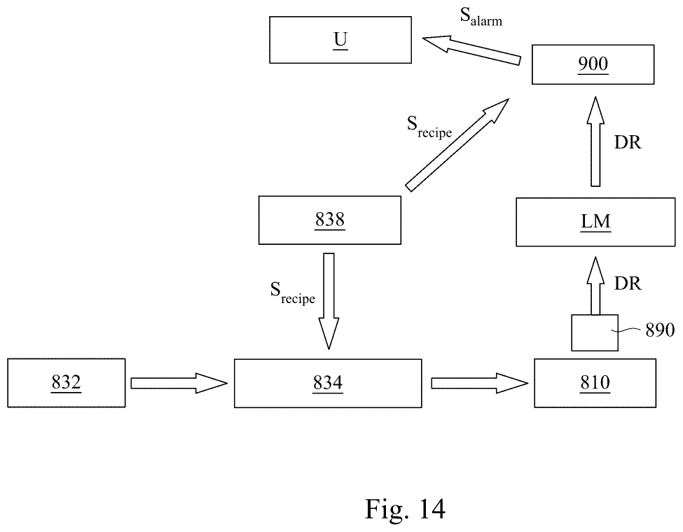

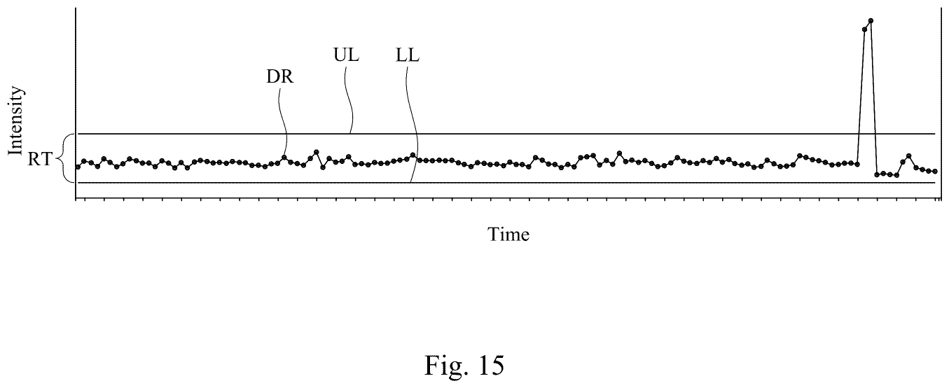

FIG. 14 is a block diagram of a semiconductor fabrication apparatus according to some embodiments of the present disclosure. Reference is made to FIGS. 12A-14. The method M3 may be performed by plural elements of the semiconductor fabrication apparatus. The moving mechanism 830 may include an encoder 838 configured to provide a recipe S_{recipe} of a vertical motion for the motor 832 to move the lead screw 834, thereby moving the wafer platform 810, as the step S32. The distance sensor 890 may measure a position of the wafer platform 810 and send a signal DR including the detection result to the digital logic control module LM, as the step S31. An information technology (IT) system 900 may communicate with the digital logic control module LM for receiving the signal DR (referring to FIG. 15 later) including the detection result, and receive the recipe S_{recipe} from the encoder 838, and make a determination based on the signal DR and the recipe S_{recipe}, as the step S33. In some embodiments, the recipe S_{recipe} may be consider as a theoretical value for checking if the position of the wafer platform 810 is correct. For example, by adding tolerance values, the recipe S_{recipe} may correspond to a range RT with an upper limit UL and a lower limit LL (referring to FIG. 15 later). The determination of the IT system 900 may include compare the signal DR with the range RT (referring to FIG. 15 later). When the signal DR is within the range RT (referring to FIG. 15 later), the IT system 900 may control the components (e.g., the gas supply system 840, the gas exhaust system 850, and the RF generator 860) in the chamber to perform a semiconductor process on the wafer W, as the step S34. And, when the signal DR is out of the range RT (referring to FIG. 15 later), the IT system 900 may send an alarm signal Sₐₗₐᵣₘ to an operator/user U1, as the step S35.

The IT system 900 is generally an information system, a communications system, or, more specifically speaking, a computer system—including all hardware, software, and peripheral equipment. The IT system 900 may be a combination of hardware components, software, and other equipment to make a system whose core purpose is to accomplish a data processing need such as the automatic acquisition, storage, analysis, evaluation, manipulation, management, movement, control, display, switching, interchange, transmission or reception of data. In some embodiments, IT systems 900 may include ground systems in support of hardware. The IT system 900 may be a computer, including a computer-readable storage medium and a processor coupled to the computer-readable storage medium. The computer-readable storage medium of the IT system 900 stores program that controls various steps of the processing methods M1, M2, and M3 (referring to FIGS. 3A, 11A, 13A) performed in the semiconductor fabrication apparatus. The IT system 900 controls the operations of the semiconductor fabrication apparatus by using the processor reading out and executing the program stored in the storage medium. The program may be one that has been stored in the computer-readable storage medium, or may be one that has been installed to the storage medium of the IT system 900. In some other embodiments, the computer-readable storage medium of the digital logic control module LM stores program that controls various steps of the processing methods M1, M2, and M3 (referring to FIGS. 3A, 11A, 13A) performed in the semiconductor fabrication apparatus. The digital logic control module LM controls the operations of the semiconductor fabrication apparatus by using the processor reading out and executing the program stored in the storage medium. The program may be one that has been stored in the computer-readable storage medium, or may be one that has been installed to the storage medium of the digital logic control module LM. In some examples, the IT system 900 may be referred to as a controller.

FIG. 15 is a detection result of the distance sensors according to some embodiments of the present disclosure. The real-time signal DR may be any one of the detection result measured at the step S12 in FIG. 3A, the measuring step S22 in FIG. 11A, the measuring step S31 in FIG. 13A. The range RT may be any one of the detection interval used at the determination step S13 in FIG. 3A, the theoretical range used at the determination step S23 in FIG. 11A, and the theoretical range used at the determination step S33 in FIG. 13A. Thus, determination step S13 in FIG. 3A, the determination step S23 in FIG. 11A, and the determination step S33 in FIG. 13A may compare the signal DR to the range RT, which can be defined by an upper limit UL and a lower limit LL set by user on the digital logic control module LM.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that during a wafer transferring process, the height of the stage can be measured and checked by using the distance sensor before the robot arm extends into the chamber, thereby avoiding the collision between the robot arm and the stage. Another advantage is that a method for wafer height detection and warning for various machines is designed to improve product yield rate and reduce the risk of wafer scrap.

According to some embodiments of the present disclosure, a method includes vertically moving a shelf in a chamber; using a distance sensor, measuring a vertical position of the shelf; determining whether a vertical position of a target stage of the shelf is within an acceptable range; and in response to the vertical position of the target stage is within an acceptable range, moving a wafer onto or away from the target stage.

According to some embodiments of the present disclosure, a method includes vertically moving a wafer platform in a chamber; using a distance sensor, measuring a vertical position of the wafer platform; determining whether the vertical position of the wafer platform is within an acceptable range; and in response to the vertical position of the wafer platform is within the acceptable range, performing a semiconductor process on a wafer on the wafer platform.

According to some embodiments of the present disclosure, an apparatus for processing a wafer is provided. The apparatus includes a chamber, a shelf in the chamber, a robot arm, a moving mechanism, a distance sensor, and a controller. The shelf comprises a plurality of stages, and each of the stages is configured for supporting a wafer. The robot arm operable to transfer the wafer. The moving mechanism is operatively connected with the shelf for vertically displacing the shelf. The distance sensor is configured for measuring a vertical position of the shelf. The controller is electrically connected with the distance sensor and the moving mechanism, wherein the controller is configured for controlling the robot arm to move the wafer onto or away from a target one of the stages when the vertical position of the shelf is within an acceptable range corresponding to the target one of the stages.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
vertically moving a shelf in a chamber;
using a distance sensor, measuring a vertical position of the shelf;
determining whether a vertical position of a target stage of the shelf is within an acceptable range; and
in response to the vertical position of the target stage is within the acceptable range, moving a wafer onto or away from the target stage.

2. The method of claim 1, further comprising:
in response to the vertical position of the target stage is outside the acceptable range, sending out an alarm massage.

3. The method of claim 1, wherein the distance sensor is above the shelf.

4. The method of claim 1, wherein measuring the vertical position of the shelf comprises:
measuring a vertical position of a topmost stage of the shelf.

5. The method of claim 4, wherein measuring the vertical position of the topmost stage of the shelf comprises:
using the distance sensor, emitting a laser beam onto the topmost stage of the shelf.

6. The method of claim 5, wherein the laser beam emitted by the distance sensor passes through a transparent plate of the chamber.

7. The method of claim 1, wherein the distance sensor is below the shelf.

8. The method of claim 1, wherein measuring the vertical position of the shelf comprises:
measuring a distance from the distance sensor to a bottom of a chamber wall.

9. The method of claim 8, wherein measuring the distance from the distance sensor to the bottom of the chamber wall comprises:
using the distance sensor, emitting a laser beam onto the bottom of the chamber wall.

10. The method of claim 1, wherein vertically moving the shelf in the chamber is performed such that the target stage of the shelf is laterally aligned with a slot of the chamber, and moving the wafer onto or away from the target stage comprises:
extending a robot arm through the slot of the chamber.

11. A method, comprising:
vertically moving a wafer platform in a chamber;
using a distance sensor, measuring a vertical position of the wafer platform;
determining whether the vertical position of the wafer platform is within an acceptable range; and
in response to the vertical position of the wafer platform is within the acceptable range, performing a semiconductor process on a wafer on the wafer platform.

12. The method of claim 11, further comprising:
in response to the vertical position of the wafer platform is within the acceptable range, prior to the semiconductor process, placing the wafer on the wafer platform.

13. The method of claim 11, further comprising:
in response to the vertical position of the wafer platform is outside the acceptable range, sending out an alarm massage.

14. The method of claim 11, wherein the semiconductor process comprises:
depositing a material layer on the wafer.

15. The method of claim 11, wherein the distance sensor is external to the chamber.

16. An apparatus for processing a wafer, comprising:
a chamber;
a shelf in the chamber, wherein the shelf comprises a plurality of stages, and each of the stages is configured for supporting the wafer;
a robot arm operable to transfer the wafer;
a moving mechanism operatively connected with the shelf for vertically displacing the shelf;
a distance sensor configured for measuring a vertical position of the shelf; and
a controller electrically connected with the distance sensor and the moving mechanism, wherein the controller is configured for controlling the robot arm to move the wafer onto or away from a target one of the stages when the vertical position of the shelf is within an acceptable range corresponding to the target one of the stages.

17. The apparatus of claim 16, wherein the distance sensor is above the shelf.

18. The apparatus of claim 16, wherein the distance sensor is below the shelf.

19. The apparatus of claim 16, wherein the controller is configured for sending out an alarm massage when the vertical position of the shelf is out of a detection interval corresponding to the target one of the stages.

20. The apparatus of claim 16, wherein the distance sensor is external to the chamber.
